(19) United States
(12) Patent Application Publication
(10) Pub. No.: US 2026/0163551 A1
(43) Pub. Date: Jun. 11, 2026

(54) BULK ACOUSTIC WAVE DEVICE WITH SOLID ACOUSTIC MIRROR HAVING METAL LAYERS

(71) Applicant: Skyworks Solutions, Inc., Irvine, CA (US)

(72) Inventors: Jun Sekimoto, Suita-Shi (JP); Junki Hayashi, Osaka-Shi (JP); Yuya Hiramatsu, Neyagawa-Shi (JP)

(21) Appl. No.: 19/389,852

(22) Filed: Nov. 14, 2025

Related U.S. Application Data
(60) Provisional application No. 63/730,665, filed on Dec. 11, 2024.
(60) Provisional application No. 63/730,697, filed on Dec. 11, 2024.

(51) Int. Cl. H03H 9/17; H03H 9/02; H03H 9/56

(52) U.S. Cl. CPC H03H 9/175; H03H 9/02015; H03H 9/02086; H03H 9/02157; H03H 9/568

(57) ABSTRACT

A bulk acoustic wave device configured to excite an overtone mode as a main mode is disclosed. The bulk acoustic wave device can include a solid acoustic mirror and a piezoelectric stack. The solid acoustic mirror includes alternating low acoustic impedance metal layers and high acoustic impedance metal layers. The piezoelectric stack includes a first electrode, a second electrode, and a piezoelectric structure between the first electrode and the second electrode. The piezoelectric structure has a first piezoelectric layer with a first polarity orientation and a second piezoelectric layer with a second polarity orientation. The first polarity orientation and the second polarity orientation can be substantially opposite.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/730,665, filed on Dec. 11, 2024, titled “BULK ACOUSTIC WAVE DEVICE WITH SOLID ACOUSTIC MIRROR HAVING METAL LAYERS” and U.S. Provisional Patent Application No. 63/730,697, filed on Dec. 11, 2024, titled “BULK ACOUSTIC WAVE DEVICE WITH CONDUCTIVE SOLID ACOUSTIC MIRROR” are hereby incorporated by reference under 37 CFR 1.57 in their entirety herein.

### BACKGROUND

### Technical Field

Embodiments of this disclosure relate to acoustic wave devices and, more specifically, to bulk acoustic wave devices with a conductive solid acoustic reflector.

### Description of Related Technology

An acoustic wave filter can include a plurality of resonators arranged to filter a radio frequency signal. Example acoustic wave filters include surface acoustic wave (SAW) filters and bulk acoustic wave (BAW) filters. BAW filters include BAW resonators. Example BAW resonators include film bulk acoustic wave resonators (FBARs) and BAW solidly mounted resonators (SMRs). In BAW resonators, acoustic waves propagate in a bulk of a piezoelectric layer.

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer. Achieving a relatively low series resistance and a relatively low acoustic wave leakage can be significant in providing a filter with desired performance.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a bulk acoustic wave device including: a solid acoustic mirror including alternating low acoustic impedance metal layers and high acoustic impedance metal layers; and a piezoelectric stack including a first electrode, a second electrode, and a piezoelectric structure between the first electrode and the second electrode, the piezoelectric structure having a first piezoelectric layer with a first polarity orientation and a second piezoelectric layer with a second polarity orientation, the first polarity orientation and the second polarity orientation are substantially opposite so as to excite an overtone mode as a main mode of the bulk acoustic wave device.

In some embodiments, the techniques described herein relate to a bulk acoustic wave device wherein the low acoustic impedance metal layers include titanium layers.

In some embodiments, the techniques described herein relate to a bulk acoustic wave device wherein the high acoustic impedance metal layers include tungsten layers.

In some embodiments, the techniques described herein relate to a bulk acoustic wave device wherein a thickness of a layer of the low acoustic impedance metal layers is in a range between 95 nm and 105 nm.

In some embodiments, the techniques described herein relate to a bulk acoustic wave device wherein the low acoustic impedance metal layers include aluminum, magnesium, beryllium, or a metal that has an acoustic impedance of 30 MRayl or less.

In some embodiments, the techniques described herein relate to a bulk acoustic wave device wherein the high acoustic impedance metal layers include tungsten (W), Osmium (Os), Iridium (Ir), or a metal that has an acoustic impedance of 90 MRayl or greater.

In some embodiments, the techniques described herein relate to a bulk acoustic wave device wherein the first piezoelectric layer is an aluminum nitride layer with crystal orientation of (0±5, 0±5, 0±5) Euler angle.

In some embodiments, the techniques described herein relate to a bulk acoustic wave device wherein the second piezoelectric layer is an aluminum nitride layer with crystal orientation of (0±5, 180±5, 0±5) Euler angle.

In some embodiments, the techniques described herein relate to a bulk acoustic wave device wherein: the low acoustic impedance metal layers include a titanium layer having a thickness in a range between 95 nm and 105 nm; the high acoustic impedance metal layers include a tungsten layers having a thickness in a range between 85 nm and 95 nm; and a thickness of the piezoelectric structure is 400 nm or more.

In some embodiments, the techniques described herein relate to a bulk acoustic wave device wherein the piezoelectric structure has a thickness in a range between 400 nm and 500 nm.

In some embodiments, the techniques described herein relate to a bulk acoustic wave device wherein the piezoelectric structure has a thickness that enables the bulk acoustic wave device to operate at a frequency of 10 GHz or higher.

In some embodiments, the techniques described herein relate to a bulk acoustic wave device wherein the piezoelectric structure further includes a third piezoelectric layer with a third polarity orientation positioned between the second piezoelectric layer and the second electrode.

In some embodiments, the techniques described herein relate to a bulk acoustic wave device wherein the second polarity orientation and the third polarity orientation are substantially opposite.

In some embodiments, the techniques described herein relate to a bulk acoustic wave device wherein the piezoelectric structure has a thickness in a range between 740 nm and 820 nm.

In some embodiments, the techniques described herein relate to a bulk acoustic wave device further including a frame structure in a frame region.

In some embodiments, the techniques described herein relate to a bulk acoustic wave device wherein the frame structure includes a recessed frame structure and a raised frame structure.

In some embodiments, the techniques described herein relate to a bulk acoustic wave device wherein the piezoelectric layer is less piezoelectric in the frame region than in a main active region.

In some embodiments, the techniques described herein relate to a bulk acoustic wave device further including a passivation layer over the second electrode.

In some embodiments, the techniques described herein relate to a bulk acoustic wave device wherein the first piezoelectric layer is in contact with the second piezoelectric layer.

In some embodiments, the techniques described herein relate to an acoustic wave filter including: the bulk acoustic wave device; and a plurality of other acoustic wave devices coupled to the bulk acoustic wave device.

In some aspects, the techniques described herein relate to a radio frequency module including: an acoustic wave filter including a bulk acoustic wave device including a solid acoustic mirror and a piezoelectric stack, the solid acoustic mirror including alternating low acoustic impedance metal layers and high acoustic impedance metal layers, the piezoelectric stack including a first electrode, a second electrode, and a piezoelectric structure between the first electrode and the second electrode, the piezoelectric structure having a first piezoelectric layer with a first polarity orientation and a second piezoelectric layer with a second polarity orientation, the first polarity orientation and the second polarity orientation are substantially opposite; and a radio frequency circuit element coupled to the acoustic wave filter, the acoustic wave filter and the radio frequency circuit element being enclosed within a common package.

In some aspects, the techniques described herein relate to a wireless communication device including: an acoustic wave filter including a bulk acoustic wave device including a solid acoustic mirror and a piezoelectric stack, the solid acoustic mirror including alternating low acoustic impedance metal layers and high acoustic impedance metal layers, the piezoelectric stack including a first electrode, a second electrode, and a piezoelectric structure between the first electrode and the second electrode, the piezoelectric structure having a first piezoelectric layer with a first polarity orientation and a second piezoelectric layer with a second polarity orientation, the first polarity orientation and the second polarity orientation are substantially opposite; an antenna operatively coupled to the acoustic wave filter; a radio frequency amplifier operatively coupled to the acoustic wave filter and configured to amplify a radio frequency signal; and a transceiver in communication with the radio frequency amplifier.

In some aspects, the techniques described herein relate to a bulk acoustic wave device including: a conductive solid acoustic mirror including a low acoustic impedance metal layer and a high acoustic impedance metal layer; and a piezoelectric stack including a first electrode, a second electrode, and a piezoelectric structure between the first electrode and the second electrode, the piezoelectric structure having a first piezoelectric layer with a first crystalline axis and a second piezoelectric layer with a second crystalline axis, the first crystalline axis and the second crystalline axis being different so as to excite an overtone mode as a main mode of the bulk acoustic wave device.

In some embodiments, the techniques described herein relate to a bulk acoustic wave device wherein the low acoustic impedance metal layer includes a titanium layer.

In some embodiments, the techniques described herein relate to a bulk acoustic wave device wherein the high acoustic impedance metal layer includes a tungsten layer.

In some embodiments, the techniques described herein relate to a bulk acoustic wave device wherein a thickness of the low acoustic impedance metal layer is in a range between 95 nm and 105 nm.

In some embodiments, the techniques described herein relate to a bulk acoustic wave device wherein the low acoustic impedance metal layer includes aluminum, magnesium, beryllium, or a metal that has an acoustic impedance of 30 MRayl or less.

In some embodiments, the techniques described herein relate to a bulk acoustic wave device wherein the high acoustic impedance metal layer includes tungsten (W), Osmium (Os), Iridium (Ir), or a metal that has an acoustic impedance of 90 MRayl or greater.

In some embodiments, the techniques described herein relate to a bulk acoustic wave device wherein the first piezoelectric layer is an aluminum nitride layer with crystal orientation of (0±5, 0±5, 0±5) Euler angle.

In some embodiments, the techniques described herein relate to a bulk acoustic wave device wherein the second piezoelectric layer is an aluminum nitride layer with crystal orientation of (0±5, 180±5, 0±5) Euler angle.

In some embodiments, the techniques described herein relate to a bulk acoustic wave device wherein: the low acoustic impedance metal layer includes a titanium layer having a thickness in a range between 95 nm and 105 nm; the high acoustic impedance metal layer includes a tungsten layers having a thickness in a range between 85 nm and 95 nm; and a thickness of the piezoelectric structure is 400 nm or more.

In some embodiments, the techniques described herein relate to a bulk acoustic wave device wherein the piezoelectric structure has a thickness in a range between 400 nm and 500 nm.

In some embodiments, the techniques described herein relate to a bulk acoustic wave device wherein the first crystalline axis and the second crystalline axis are substantially opposite from each other.

In some embodiments, the techniques described herein relate to a bulk acoustic wave device wherein the piezoelectric structure further includes a third piezoelectric layer with a third crystalline axis positioned between the second piezoelectric layer and the second electrode, the second crystalline axis and the third crystalline axis are substantially opposite from each other.

In some embodiments, the techniques described herein relate to a bulk acoustic wave device wherein the piezoelectric structure has a thickness in a range between 740 nm and 820 nm.

In some embodiments, the techniques described herein relate to a bulk acoustic wave device further including a frame structure in a frame region.

In some embodiments, the techniques described herein relate to a bulk acoustic wave device wherein the frame structure includes a recessed frame structure and a raised frame structure.

In some embodiments, the techniques described herein relate to a bulk acoustic wave device wherein the piezoelectric layer is less piezoelectric in the frame region than in a main active region.

In some embodiments, the techniques described herein relate to a bulk acoustic wave device further including a passivation layer over the second electrode.

In some embodiments, the techniques described herein relate to an acoustic wave filter including: the bulk acoustic wave device; and a plurality of other acoustic wave devices coupled to the bulk acoustic wave device.

In some aspects, the techniques described herein relate to a radio frequency module including: an acoustic wave filter including a bulk acoustic wave device including a solid acoustic mirror and a piezoelectric stack, the solid acoustic mirror including alternating low acoustic impedance metal layers and high acoustic impedance metal layers, the piezoelectric stack including a first electrode, a second electrode, and a piezoelectric structure between the first electrode and the second electrode, the piezoelectric structure having a first piezoelectric layer with a first crystalline axis and a second piezoelectric layer with a second crystalline axis, the first crystalline axis and the second crystalline axis being different so as to excite an overtone mode as a main mode of the bulk acoustic wave device; and a radio frequency circuit element coupled to the acoustic wave filter, the acoustic wave filter and the radio frequency circuit element being enclosed within a common package.

In some aspects, the techniques described herein relate to a wireless communication device including: an acoustic wave filter including a bulk acoustic wave device including a solid acoustic mirror and a piezoelectric stack, the solid acoustic mirror including alternating low acoustic impedance metal layers and high acoustic impedance metal layers, the piezoelectric stack including a first electrode, a second electrode, and a piezoelectric structure between the first electrode and the second electrode, the piezoelectric structure having a first piezoelectric layer with a first crystalline axis and a second piezoelectric layer with a second crystalline axis, the first crystalline axis and the second crystalline axis being different so as to excite an overtone mode as a main mode of the bulk acoustic wave device; an antenna operatively coupled to the acoustic wave filter; a radio frequency amplifier operatively coupled to the acoustic wave filter and configured to amplify a radio frequency signal; and a transceiver in communication with the radio frequency amplifier.

### BRIEF DESCRIPTION OF THE DRAWINGS

Embodiments of this disclosure will now be described, by way of non-limiting example, with reference to the accompanying drawings.

FIG. 1 is a schematic cross-sectional side view of a BAW device according to an embodiment.

FIGS. 2A and 2B are graphs showing simulated admittance of various BAW resonators.

FIGS. 3A-3E are examples electrode and piezoelectric stacks that can be implemented in the BAW device of FIG. 1.

FIG. 4 is a schematic cross-sectional side view of a BAW device according to an embodiment.

FIG. 5 is a schematic diagram of a ladder filter that includes overtone mode BAW resonators according to an embodiment.

FIG. 6 is a schematic diagram of a ladder filter that includes overtone mode BAW resonators and fundamental mode BAW resonators according to an embodiment.

FIG. 7 is a schematic diagram of a ladder filter that includes overtone mode BAW resonators and fundamental mode BAW resonators according to an embodiment.

FIG. 8 is a schematic diagram of a lattice filter that includes a bulk acoustic wave resonator according to an embodiment.

FIG. 9 is a schematic diagram of a hybrid ladder lattice filter that includes a bulk acoustic wave resonator according to an embodiment.

FIG. 10A is a schematic diagram of an acoustic wave filter.

FIG. 10B is a schematic diagram of a duplexer.

FIG. 10C is a schematic diagram of a multiplexer with hard multiplexing.

FIG. 10D is a schematic diagram of a multiplexer with switched multiplexing.

FIG. 10E is a schematic diagram of a multiplexer with a combination of hard multiplexing and switched multiplexing.

FIG. 11 is a schematic diagram of a radio frequency module that includes an acoustic wave filter according to an embodiment.

FIG. 12 is a schematic block diagram of a module that includes an antenna switch and duplexers according to an embodiment.

FIG. 13 is a schematic block diagram of a module that includes a power amplifier, a radio frequency switch, and duplexers according to an embodiment.

FIG. 14 is a schematic block diagram of a module that includes a low noise amplifier, a radio frequency switch, and filters according to an embodiment.

FIG. 15 is a schematic diagram of a radio frequency module that includes an acoustic wave filter according to an embodiment.

FIG. 16 is a schematic block diagram of a wireless communication device that includes a filter according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

A bulk acoustic wave (BAW) device can include an acoustic reflector that can confine acoustic energy within the active region of the BAW device to enhance its performance. An air gap reflector and a solidly mounted reflector (SMR), such as a Bragg reflector, are examples of acoustic reflectors. In some applications, Bragg reflectors may offer advantages over air gap reflectors by enhancing performance through efficient wave confinement. Bragg reflectors can provide relatively high reflectivity across a broad frequency range due to their alternating material layers, making them suitable for multiple frequency ranges. Bragg reflectors also demonstrate a relatively high thermal stability since their solid layers can maintain consistent performance despite temperature fluctuations. Additionally, Bragg reflectors can have relatively high mechanical robustness.

An SMR-BAW device includes a Bragg reflector, a first electrode, a second electrode, and a piezoelectric layer between the first electrode and the second electrode. The Bragg reflector can include alternating low impedance dielectric layers (e.g., silicon dioxide layers) and high impedance layers (e.g., tungsten layers). To mitigate resonance frequency decrease of a relatively high frequency operation, thicknesses of the first electrode and the second electrode are made thinner. However, the relatively thin first and second electrodes can cause a series resistance increase. For example, for a 15GHz operation at 50 ohm matching with 50 nm thick ruthenium (Ru) layers as the first and second electrodes and a 100 nm thick aluminum nitride (AlN), the resistance at each of the first and second electrodes can be about 1.42 Ω. Therefore, the series resistance can be about 2.84 Ω. This relatively high series resistance can degrade the Y characteristic of the resonant frequency (fs).

In order to reduce the series resistance, the low impedance dielectric layers of the Bragg reflector can be replaced with metal layers with a lower acoustic impedance than the high impedance layers. When the silicon dioxide layers are replaced with titanium (Ti) layers, the series resistance can be reduced to about 1.75 Ω. The reduction in the series resistance can mitigate the degradation of the Y characteristic of the resonant frequency (fs). However, the Y characteristic of the anti-resonant frequency (fp) can be degraded due to acoustic wave leakage in the Bragg reflector. Accordingly, it can be challenging to have a relatively low series resistance and a relatively low acoustic wave leakage.

Aspects of this disclosure relate to an SMR-BAW device with a relatively low series resistance and a relatively low acoustic wave leakage. An SMR-BAW device according to an embodiment includes a solid acoustic reflector (e.g., a Bragg reflector), a first electrode, a second electrode, and a piezoelectric structure including a first piezoelectric layer and a second piezoelectric layer. The piezoelectric structure is positioned between the first electrode and the second electrode. The first and second piezoelectric layers can have different polarity or c-axis orientations. The first and second piezoelectric layers can configure to excite an overtone mode as a main mode for the BAW device. For example, the first and second piezoelectric layers can have c-axes or the polarity orientations oriented in substantially opposite directions. The solid acoustic reflector includes alternating low impedance conductive layers (e.g., alternating low impedance metal layers) and high impedance conductive layers (high impedance metal layers). A combination of the conductive solid acoustic reflector that includes the alternating low impedance conductive layers and high impedance conductive layer and the piezoelectric structure that includes the first and second piezoelectric layers with different c-axis orientations can contribute to reducing the series resistance and reducing the acoustic wave leakage, which can provide a higher coupling coefficient (k2) and/or larger admittance ratio.

BAW devices with stacked piezoelectric layers disclosed herein can excite overtone modes with relatively high resonant frequencies. Such BAW devices can excite an overtone mode with a resonant frequency in a range from 5 GHz to 20 GHz, such as in a range from 5 GHz to 12 GHz. Some such BAW devices can have a resonant frequency in a range from 5 GHz to 7.5 GHz. These BAW devices can be used in band pass filters having a passband over 5 GHz and within fifth generation (5G) New Radio (NR) Frequency Range 1(FR 1 ). Some BAW devices with stacked piezoelectric layers disclosed herein can have a resonant frequency in a range from 7 GHz to 10 GHz.

BAW devices with a plurality of stacked piezoelectric layers with a combined thickness in a range from 0.2 micrometer (um) to 5 um can excite an overtone mode with a resonant frequency in a range from 5 GHz to 12 GHz. In some instances, such stacked piezoelectric layers can have a combined thickness in a range from 2 um to 5 um. The stacked piezoelectric layers can have c-axes implemented in accordance with any suitable principles and advantages disclosed herein. Such devices have a thicker piezoelectric and electrode layer stack than a similar BAW resonator with a single piezoelectric layer and the same resonant frequency for a fundamental mode. With the thicker stack, higher power handling can be achieved. BAW devices with stacked piezoelectric layers that each include aluminum nitride and with a combined thickness in a range from 0.2 um to 5um can excite an overtone mode with a resonant frequency in a range from 5 GHz to 12 GHz. Any other suitable piezoelectric material can alternatively or additionally be used.

While embodiments disclosed herein may relate to BAW devices that excite a second overtone mode or a third overtone mode, any suitable principles and advantages disclosed herein can be applied to a BAW device with more stacked piezoelectric layers that is arranged to excite a fourth overtone mode, a fifth overtone mode, or higher overtone mode. Such BAW devices can excite an overtone mode with a resonant frequency in a range from 5 GHz to 20 GHz.

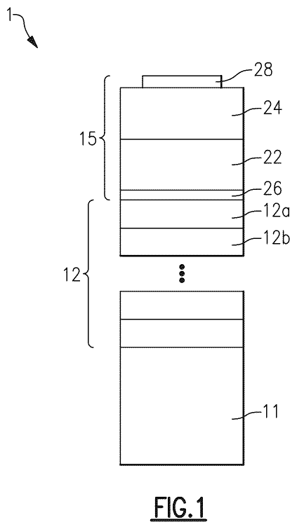

FIG. 1 is a schematic cross-sectional side view of a bulk acoustic wave (BAW) device 1 according to an embodiment. As illustrated, the BAW device 1 can include a support substrate 11, a solid acoustic mirror 12, and a piezoelectric stack 15. The piezoelectric stack 15 includes a piezoelectric structure having a plurality of piezoelectric layers (e.g., a first piezoelectric layer 22 and a second piezoelectric layer 24), a first electrode 26, and a second electrode 28. Although FIG. 1 illustrates two piezoelectric layers included in the piezoelectric structure, there may be three or more piezoelectric layers in the piezoelectric structure.

An active region or active domain of the BAW device 1 can be defined by a portion of the stacked piezoelectric layers that is in contact with both the first electrode 26 and the second electrode 28 and overlaps an acoustic reflector, such as the solid acoustic mirror 12. The active region corresponds to where voltage is applied on opposing sides of the stack of piezoelectric layers over the acoustic reflector. The active region can be the acoustically active region of the BAW device 1. The main acoustically active region can provide a main mode of the BAW device 1. In some applications, the main acoustically active region can be smaller than the active region.

The support substrate 11 can be a silicon substrate. The support substrate 11 can be any other suitable support substrate, such as a substrate of quartz, silicon carbide, sapphire, glass, gallium arsenide, or any suitable ceramic (e.g., spinel, alumina, etc.).

The solid acoustic mirror 12 is an example of an acoustic reflector. As illustrated, the solid acoustic mirror 12 is located above the support substrate 11. The solid acoustic mirror 12 is positioned between the support substrate 11 and the first electrode 26. The solid acoustic mirror 12 can be a conductive solid acoustic mirror that includes alternating low acoustic impedance and high impedance conductive layers. The solid acoustic mirror 12 can include alternating low acoustic impedance metal layers 12a and high acoustic impedance metal layers 12b. There can be any suitable number of alternating low acoustic impedance metal layers 12a and high acoustic impedance metal layers 12b. In some embodiments, a material of the low acoustic impedance metal layers 12a can include titanium (Ti), aluminum (Al), magnesium (Mg), beryllium (Be), or a metal that has an acoustic impedance of 30 MRayl or less, and a material of the high acoustic impedance metal layers 12b can include tungsten (W), Osmium (Os), Iridium (Ir), gold (Au), ruthenium (Ru), molybdenum (Mo), platinum (Pt), or a metal that has an acoustic impedance of 60 MRayl or greater, or 90 MRayl or greater. In some embodiments, the materials of the low acoustic impedance layers 12a and the high acoustic impedance layers 12b can be selected to have an acoustic impedance ratio of 2 or greater, or 3 or greater. For example, the solid acoustic mirror 12 can include alternating titanium (Ti) layers as the low acoustic impedance metal layers 12a and tungsten (W) layers as the high impedance metal layers 12b.

A thickness of the low acoustic impedance metal layer 12a can be generally similar to a thickness of the high acoustic impedance metal layer 12b. In some embodiments, the thickness of the low acoustic impedance metal layer 12a can be greater than the thickness of the high acoustic impedance metal layer 12b. For example, the low acoustic impedance metal layers 12a can each have a thickness in a range between 95 nm and 105 nm, 98 nm and 102 nm, or 99.6 nm and 101 nm and the high acoustic impedance metal layers 12b can each have a thickness in a range between 85 nm and 95 nm, or 88 nm and 92 nm.

The first piezoelectric layer 22 and the second piezoelectric layer 24 of the piezoelectric stack 15 can have different polarities. A first polarity orientation of the first piezoelectric layer 22 can be different from a second polarity orientation of the second piezoelectric layer 24. In some embodiments, the polarity orientations of the first piezoelectric layer 22 and the second piezoelectric layer 24 can be inverted such that the crystallographic orientation of the first piezoelectric layer 22 is opposite the crystallographic orientation of the second piezoelectric layer 24. For example, the first piezoelectric layer 22 can include an aluminum nitride (AlN) layer that has (0±5, 0±5, 0±5) in Euler angle as its crystal orientation and the second piezoelectric layer 24 can include an aluminum nitride (AlN) layer that has (0±5, 180±5, 0±5) in Euler angle as its crystal orientation.

A combination of the first piezoelectric layer 22, the second piezoelectric layer 24, and the solid acoustic mirror 12 disclosed herein can reduce series resistance and the acoustic wave leakage in the BAW device 1, thereby improving its performance.

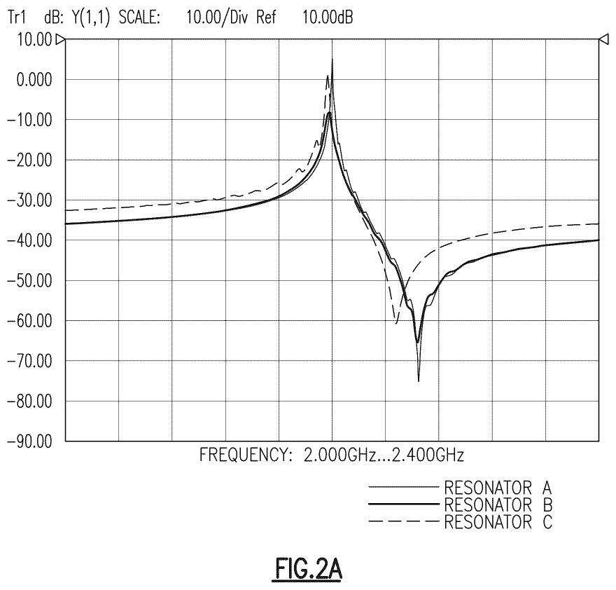

FIG. 2A is a graph showing simulated admittance of three BAW resonators (Resonators A, B and C). Resonators A and B used in the simulation of FIG. 2A are examples of the BAW device 1 of FIG. 1. Resonator A includes three pairs of titanium (Ti) and tungsten (W) layers as the solid acoustic mirror 12, ruthenium (Ru) layers as the first and second electrodes 26, 28, an aluminum nitride (AlN) layer with (0, 0, 0) in Euler angle as its crystal orientation as the first piezoelectric layer 22, and an aluminum nitride (AlN) layer with (0, 180, 0) in Euler angle as its crystal orientation as the second piezoelectric layer 24. Resonator B is similar to Resonator A but Resonator B includes two pairs of titanium (Ti) and tungsten (W) layers as the solid acoustic mirror 12 instead of three. Resonator C is similar to Resonator A. However, Resonator C includes a single piezoelectric layer instead of the piezoelectric structure that includes the first piezoelectric layer 22 and the second piezoelectric layer 24.

FIG. 2A indicates that the Y characteristic of the resonant frequency (fs) and the Y characteristic of the anti-resonant frequency (fp) of Resonator A are improved relative to Resonator C, and the Y characteristic of the anti-resonant frequency (fp) of Resonator B is improved relative to Resonator C. Also, FIG. 2A indicates that three pairs of titanium (Ti) and tungsten (W) layers as the solid acoustic mirror 12 can improve the Y characteristic of the resonant frequency (fs) and the Y characteristic of the anti-resonant frequency (fp) more than the two pairs of titanium (Ti) and tungsten (W) layers as the solid acoustic mirror 12.

FIG. 2B is a graph showing simulated admittance of three BAW resonators (Resonators A, D, and E). Resonators A and D used in the simulation of FIG. 2B are examples of the BAW device 1 of FIG. 1. Resonator D is similar to Resonator A but Resonator D includes an additional aluminum nitride (AlN) layer with (0, 0, 0) in Euler angle as its crystal orientation between the second piezoelectric layer 24 and the second electrode 28. Resonator E is similar to Resonator C. However, Resonator E includes three pairs of alternating silicon dioxide (SiO₂) layers as low impedance layers and tungsten (W) layers as high impedance layers instead of the titanium-tungsten layers. The total thickness of the piezoelectric layer in Resonator A is set to 440 nm, the total thickness of the piezoelectric layer in Resonator D is set to 786 nm, and the total thickness of the piezoelectric layer in Resonator E is set to 100 nm.

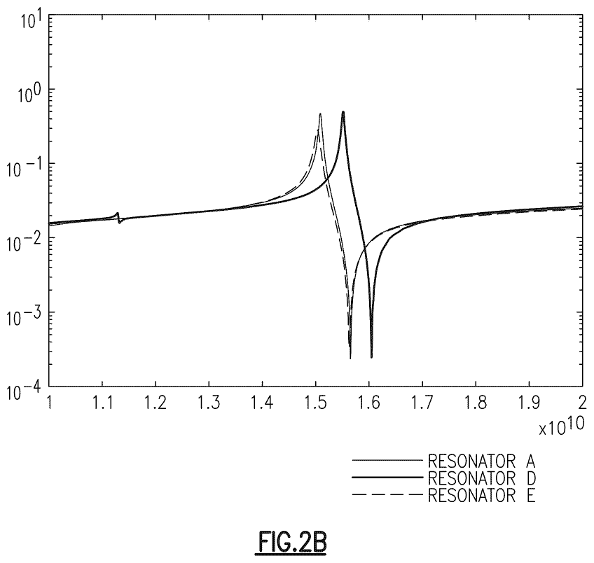

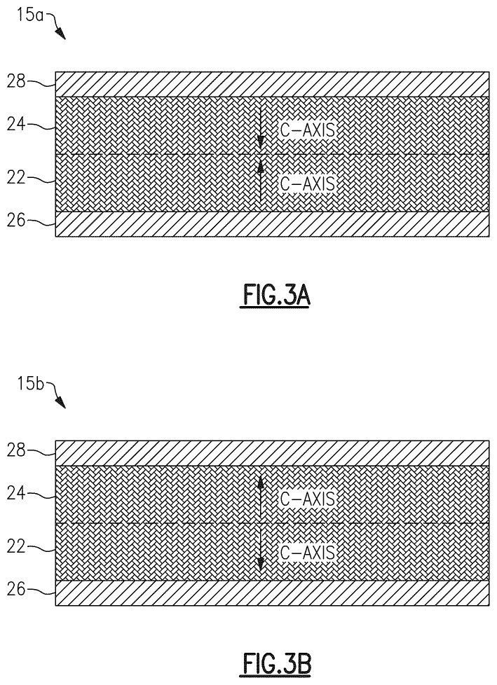

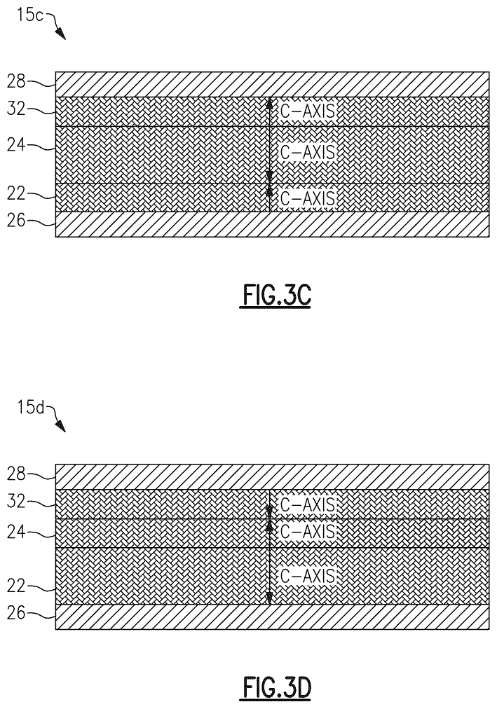

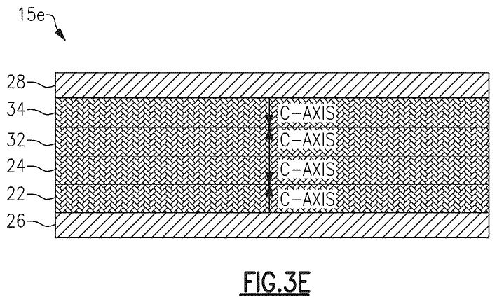

FIG. 2B indicates that the Y characteristic of the resonant frequency (fs) and the Y characteristic of the anti-resonant frequency (fp) of Resonators A and D are improved relative to Resonator E. As demonstrated in FIG. 2B, the piezoelectric structure of the piezoelectric stack 15 can include more than two piezoelectric layers. FIGS. 3A-3E are examples of piezoelectric stacks 15a-15e that can be implemented as the piezoelectric stack 15 of BAW device 1.

FIG. 3A is a schematic cross-sectional side view of a piezoelectric stack 15a that can be implemented as the piezoelectric stack 15 of the BAW device 1 of FIG. 1. In the piezoelectric stack 15a, the first piezoelectric layer 22 and the second piezoelectric layer 24 are stacked with each other and positioned between the first electrode 26 and the second electrode 28. The second piezoelectric layer 24 is positioned between the first piezoelectric layer 22 and the second electrode 28. The first piezoelectric layer 22 is positioned between the first electrode 26 and the second piezoelectric layer 24. The first piezoelectric layer 22 and the second piezoelectric layer 24 can be in physical contact with each other in a main acoustically active region of the BAW device 1. In FIG. 3A, planar surfaces of first piezoelectric layer 22 and the second piezoelectric layer 24 in physical contact with each other can be parallel to a planar surface of the first electrode 26.

As shown in FIG. 3A, the first piezoelectric layer 22 and the second piezoelectric layer 24 have c-axes oriented in different directions. The c-axis of the first piezoelectric layer 22 is oriented in an opposite direction than the c-axis of the second piezoelectric layer 24. To manufacture c-axes with opposite direction growth, a seed layer can be (1) included on an interface between the first piezoelectric layer 22 and first electrode 26 and/or (2) included on an interface between the first piezoelectric layer 22 and the second piezoelectric layer 24. The c-axis of the first piezoelectric layer 22 is rotated 180° relative to the c-axis of the second piezoelectric layer 24 in FIG. 3A. The c-axis or the polarity orientation of the first piezoelectric layer 22 can be substantially opposite relative to the c-axis or polarity orientation of the second piezoelectric layer 24. Such c-axes oriented in substantially opposite directions can be rotated by an angle in a range from 170° to 190° relative to each other.

As illustrated in FIG. 3A, the c-axis of the first piezoelectric layer 22 and the c-axis of the second piezoelectric layer 24 are both oriented perpendicular to a planar surface of the first electrode 26. Similarly, the c-axis of the first piezoelectric layer 22 and the c-axis of the second piezoelectric layer 24 are both oriented perpendicular to a planar surface of the second electrode 28 in FIG. 3A. The c-axis or polarity orientation of the first piezoelectric layer 22 and/or the c-axis or polarity orientation of the second piezoelectric layer can be substantially perpendicular to a planar surface of the first electrode 26 and/or a planar surface of the second electrode 28. Such substantially perpendicular c-axes can be oriented at an angle in a range from 85° to 95° relative to a planar surface of an electrode. While a piezoelectric layer with a c-axis substantially perpendicular to a planar electrode surface is preferred in certain applications, any other suitable c-axis orientation can be implemented for a particular application.

The arrangement of the stacked piezoelectric layers 22 and 24 can excite an overtone mode or a higher order mode as a main mode for the BAW device 1. An overtone mode or a higher order mode can be a mode that is higher than the fundamental mode. The main mode can be a mode associated with a highest electromechanical coupling coefficient (kt²) among modes generated by the BAW device 1. The main mode can be one or more of: 1) the lowest order mode that the BAW device 1 operates at when excited; and 2) an operating mode of the BAW device 1 that is used for a filter that includes the BAW device 1. The overtone mode can be a second overtone mode for the BAW device 1. The overtone mode has a resonant frequency that can be about 2 times a resonant frequency of a fundamental mode of the BAW device 1. The resonant frequency for the overtone mode may not be exactly 2 times a resonant frequency of the fundamental mode due to contributions of the electrodes of the BAW device 1 to resonant frequency.

The first piezoelectric layer 22 and the second piezoelectric layer 24 can both include a same piezoelectric material. The first piezoelectric layer 22 can include aluminum nitride. The second piezoelectric layer 24 can include aluminum nitride. The first piezoelectric layer 22 and/or the second piezoelectric layer 24 can include any suitable piezoelectric material. For example, the first piezoelectric layer 22 and/or the second piezoelectric layer 24 can include zinc oxide.

The first piezoelectric layer 22 can be doped with any suitable dopant, such as scandium (Sc), chromium (Cr), magnesium (Mg), or the like. For example, the first piezoelectric layer 22 can be doped with scandium. Doping the first piezoelectric layer 22 can adjust resonant frequency. Doping the first piezoelectric layer 22 can increase the coupling coefficient k² of the BAW device 1. Doping to increase the coupling coefficient k² can be advantageous at higher frequencies where the coupling coefficient k² can be degraded. The second piezoelectric layer 24 can be doped with any suitable dopant. The second piezoelectric layer 24 can be doped with a same dopant as the first piezoelectric layer 24 in certain applications. In certain applications, the first piezoelectric layer 22 and the second piezoelectric layer 24 can be doped with different doping concentrations.

In certain applications, a combination of c-axis orientation and doping concentration can be adjusted in the second piezoelectric layer relative 24 to the first piezoelectric layer 22. The orientation of the c-axis can impact resonant frequency of a BAW device. Two or more properties of the second piezoelectric layer 24 can be adjusted relative to the first piezoelectric layer 22.

The first piezoelectric layer 22 can have approximately the same thickness as the second piezoelectric layer 24 in certain applications. The first piezoelectric layer 22 and the second piezoelectric layer 24 can have any suitable relative sizes for a particular application. For instance, the first piezoelectric layer 22 and the second piezoelectric layer 24 can have an approximately 60/40 thickness ratio in certain applications. The ratio of the first piezoelectric layer 22 and the second piezoelectric layer 24 can be selected based on parasitics associated with the BAW device 1 that includes the piezoelectric layers 22 and 24. For example, relative sizes of the piezoelectric layers 22 and 24 can be selected to provide stronger suppression of a non-linearity in the presence of parasitics that impact the piezoelectric layers 22 and 24.

The first electrode 26 can be referred to as a lower electrode. The first electrode 26 can have a relatively high acoustic impedance. The first electrode 26 can include molybdenum (Mo), tungsten (W), ruthenium (Ru), chromium (Cr), iridium (Ir), platinum (Pt), Ir/Pt, or any suitable alloy and/or combination thereof. Similarly, the second electrode 28 can have a relatively high acoustic impedance. The second electrode 28 can include Mo, W, Ru, Cr, Ir, Pt, Ir/Pt, or any suitable alloy and/or combination thereof. The second electrode 28 can be formed of the same material as the first electrode 26 in certain instances. The second electrode 28 can be referred to as an upper electrode. The thickness of the first electrode 26 can be approximately the same as the thickness of the second electrode 28 in the BAW material stack 15. The first electrode 26 and the second electrode 28 can be the only electrodes of the BAW device 1.

FIG. 3B is a schematic cross-sectional side view of a piezoelectric stack 15b that can be implemented as the piezoelectric stack 15 of the BAW device 1 of FIG. 1. The piezoelectric stack 15b is like the piezoelectric stack 15a of FIG. 3A, except that the piezoelectric layers 22 and 24 of FIG. 3B have opposite c-axis orientations relative to corresponding piezoelectric layers 22 and 24 of FIG. 3A. The BAW device 1 that includes the piezoelectric stack 15b can have similar admittance over frequency compared to the BAW device 1 that includes the piezoelectric stack 15a.

FIG. 3C is a schematic cross-sectional side view of the piezoelectric stack 15c that can be implemented as the piezoelectric stack 15 of the BAW device 1 of FIG. 1. The piezoelectric stack 15c includes a first piezoelectric layer 22, a second piezoelectric layer 24, and a third piezoelectric layer 32. The piezoelectric layers 22, 24, 32 are stacked with each other and positioned between the first electrode 26 and the second electrode 28. Each of the piezoelectric layers 22, 24, 32 can be in physical contact with at least one other piezoelectric layer that has a different c-axis orientation. For example, the first piezoelectric layer 22 is illustrated as being adjacent to and in physical contact with the second piezoelectric layer 24. The first piezoelectric layer 22 and the second piezoelectric layer 24 have opposite c-axis orientations in FIG. 3C. As another example, the second piezoelectric layer 24 is illustrated as being adjacent to and in physical contact with the third piezoelectric layer 32. In some instances, a seed layer can be included between adjacent piezoelectric layers of the piezoelectric stack 15c. The second piezoelectric layer 24 and the third piezoelectric layer 32 have opposite c-axis orientations in FIG. 3C. In the electrode and piezoelectric stack 15c, the first piezoelectric layer 22 and the third piezoelectric layer 32 can have a same c-axis orientation.

The arrangement of the stacked piezoelectric layers 22, 24, 32 can excite an overtone mode as a main mode for a BAW resonator. The overtone mode can be a third overtone mode for the BAW device 1 that includes the piezoelectric stack 15c of FIG. 3C. The overtone mode has a resonant frequency that can be about 3 times a resonant frequency of a fundamental mode of the BAW device. The resonant frequency for the overtone mode may not be exactly 3 times a resonant frequency of the fundamental mode due to contributions of the electrodes of the BAW device to resonant frequency.

FIG. 3D is a schematic cross-sectional side view of a piezoelectric stack 15d that can be implemented as the piezoelectric stack 15 of the BAW device 1 of FIG. 1. The piezoelectric stack 15d is like the piezoelectric stack 15c of FIG. 3C, except that the piezoelectric layers 22, 24, 32 of FIG. 3D have different c-axis orientations relative to corresponding piezoelectric layers 22, 24, 32 of FIG. 3C. The piezoelectric layers 22, 24, 32 of piezoelectric stack 15d can have different respective thicknesses than the piezoelectric layers 22, 24, 32 of the piezoelectric stack 15c in certain applications. A BAW device that includes piezoelectric stack 15d can be configured to excite a third overtone mode as a main mode.

FIG. 3E is a schematic cross-sectional side view of a piezoelectric stack 15e that can be implemented as the piezoelectric stack 15 of the BAW device 1 of FIG. 1. The piezoelectric stack 15e includes a first piezoelectric layer 22, a second piezoelectric layer 24, a third piezoelectric layer 32, and a fourth piezoelectric layer 34. The piezoelectric layers 22, 24, 32, 34 are stacked with each other and positioned between the first electrode 26 and the second electrode 28. Each of the piezoelectric layers 22, 24, 32, 34 can be in physical contact with at least one other piezoelectric layer that has a different c-axis orientation. As illustrated, each of the piezoelectric layers 22, 24, 32, 34 is adjacent to at least one other piezoelectric layer with an opposite c-axis orientation.

The arrangement of the stacked piezoelectric layers 22, 24, 32, 34 can excite an overtone mode as a main mode for a BAW resonator corresponding to FIG. 3E. The overtone mode can be a second overtone mode for the BAW device. The stacked piezoelectric layers 22, 24, 32, 34 can excite the second overtone mode due to symmetry of the field distribution with a middle interface. This second overtone mode has a resonant frequency that can be about 2 times a resonant frequency of a fundamental mode of the BAW device.

The piezoelectric structure of the piezoelectric stack 15 disclosed herein can have any suitable thicknesses. For example, the thickness of the piezoelectric structure can be 400 nm or more. When the piezoelectric structure has a dual-layer structure, the thickness of the piezoelectric structure can be, for example, in a range between 400 nm and 500 nm, 420 nm and 460 nm, or 430 nm and 450 nm. When the piezoelectric structure has a tri-layer structure, the thickness of the piezoelectric structure can be, for example, in a range between 740 nm and 820 nm, 760 nm and 800 nm, or 780 nm and 790 nm. The thickness of the piezoelectric structure can be, for example, selected so as to enable the BAW device 1 to operate at a frequency of 10 GHz or higher.

The BAW device 1 can include any other suitable features that are not illustrated in FIG. 1. FIG. 4 illustrates a BAW device 1a that includes the features of the BAW device 1 and additional features.

FIG. 4 is a schematic cross-sectional side view of a BAW device 1a according to an embodiment. As illustrated, the BAW device 1a can include a support substrate 11, a solid acoustic mirror 12, a first passivation layer 13, a second passivation layer 14, the piezoelectric stack 15, and an interconnect layer 16. The BAW device 1a can also include a frame structure. The frame structure can include, for example, a recessed frame structure 17 and a raised frame structure 18. The piezoelectric stack 15 includes a plurality of piezoelectric layers 22 and 24, a first electrode 26, and a second electrode 28. The portion of the piezoelectric stack 15 indicated with dashed lines in FIG. 4 can correspond to the piezoelectric stacks 15a-15e of FIG. 3A-3E.

An active region or active domain of the BAW device 1a can be defined by a portion of the stacked piezoelectric layers that is in contact with both the first electrode 26 and the second electrode 28 and overlaps an acoustic reflector, such as the solid acoustic mirror 12 or a solid acoustic mirror. The active region corresponds to where voltage is applied on opposing sides of the stack of piezoelectric layers over the acoustic reflector. The active region can be the acoustically active region of the BAW device 1a. The BAW device 1a also includes a recessed frame region with the recessed frame structure 17 in the active region and a raised frame region with the raised frame structure 18 in the active region. The main acoustically active region can provide a main mode of the BAW device 1a. The main acoustically active region can be the central part of the active region that is free from the recessed frame structure 17 and the raised frame structure 18. The recessed frame region and the raised frame region can together be referred to as a frame region.

While the BAW device 1a includes the recessed frame structure 17 and the raised frame structure 18, other frame structures can alternatively or additionally be implemented. For example, a raised frame structure with multiple layers including a layer between an electrode of a BAW device and a piezoelectric layer can be implemented. As another example, a floating raised frame structure can be implemented. As one more example, a raised frame structure can be implemented without a recessed frame structure.

The solid acoustic mirror 12 is positioned between the support substrate 11 and the first electrode 26. In some embodiments, the solid acoustic mirror 12 can be provided at least in the active region. In the illustrated embodiment, the solid acoustic mirror 12 is provided both in the main active region and the frame region. However, in some other embodiments, the acoustic mirror 12 can be provided only in the main active region and be omitted from the frame region.

The first passivation layer 13 can be positioned between the solid acoustic mirror 12 and the first electrode 26. The first passivation layer 13 can be referred to as a lower passivation layer. The first passivation layer 13 can be a silicon dioxide layer or any other suitable passivation layer, such as aluminum oxide, silicon carbide, aluminum nitride, silicon nitride, silicon oxynitride, or the like. In certain applications, an adhesion layer can be positioned between the first passivation layer 13 and the first electrode 26 to increase adhesion between these layers. The adhesion layer can be a titanium layer, for example.

The second passivation layer 14 can be referred to as an upper passivation layer. The second passivation layer 14 can be a silicon dioxide layer or any other suitable passivation layer, such as aluminum oxide, silicon carbide, aluminum nitride, silicon nitride, silicon oxynitride, or the like. The second passivation layer 14 can be the same material as the first passivation layer 13 in certain instances. The second passivation layer 14 can have different thicknesses in different regions of the BAW device 1a. Part of the second passivation layer 14 can form at least part of the recessed frame structure 17 and/or the raised frame structure 18.

The piezoelectric structure (e.g., the first piezoelectric layer 22 and the second piezoelectric layer 24) of the piezoelectric stack 15 can be piezoelectric across the width of the BAW device 1a. However, in some embodiments, the piezoelectric structure can be more piezoelectric in the active region and less piezoelectric in regions other than the active region. As an example, the piezoelectric structure can be provided only in the active region and a layer of another material that is not piezoelectric or less piezoelectric than the piezoelectric structure can be provided in the frame region. As another example, the piezoelectric structure can be engineered in the frame region to be less piezoelectric than the piezoelectric structure in the active region.

The BAW devices disclosed herein can be implemented as acoustic wave resonators in a variety of filters. Such filters can be arranged to filter a radio frequency signal. The BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors.

FIG. 5 is a schematic diagram of a ladder filter 100 that includes BAW resonators according to an embodiment. All acoustic resonators of the ladder filter 100 can be overtone mode BAW resonators. The ladder filter 100 can be implemented in higher power applications where the overtone mode BAW resonators provide desirable power handling characteristics. The ladder filter 100 can be a transmit filter. The ladder filter 100 can be implemented in higher frequency filtering applications (e.g., filtering RF signal with a frequency of over 5 GHz). The ladder filter 100 can have a passband in a frequency range from 5 GHz to 12 GHz. The ladder filter 100 can have a passband in a frequency range from 5 GHz to an upper end of FR1. The ladder filter 100 can have a passband in a frequency range from 5 GHz to 20 GHz. The ladder filter 100 can be used in 5G NR applications. For example, the ladder filter 100 can be a band pass filter with a passband corresponding to a 5G NR operating band.

In certain applications, each BAW resonator in the ladder filter 100 can excite a second overtone mode as a main mode. In various applications, each BAW resonator in the ladder filter 100 can excite a third overtone mode as a main mode. In some applications, at least one BAW resonator in the ladder filter 100 can excite a second overtone mode as a main mode and at least one other BAW resonator can excite a third overtone mode as a main mode. One or more overtone mode BAW resonators of the ladder filter can excite a fourth or higher overtone mode as a main mode.

The ladder filter 100 is an example topology that can implement a band pass filter formed from acoustic wave resonators. In a band pass filter with a ladder filter topology, the shunt resonators can have lower resonant frequencies than the series resonators. The ladder filter 100 can be arranged to filter a radio frequency signal. As illustrated, the ladder filter 100 includes series BAW resonators R1, R3, R5, R7, R9 and shunt BAW resonators R2, R4, R6, R8 coupled between a first input/output port I/O₁ and a second input/output port I/O₂. The shunt BAW resonators can be coupled between a node between two series BAW resonators and ground GND as illustrated. Any suitable number of series BAW resonators can be in included in a ladder filter. Any suitable number of shunt BAW resonators can be included in a ladder filter. The first input/output port I/O₁ can be a transmit port and the second input/output port I/O₂ can be an antenna port. Alternatively, first input/output port I/O₁ can be a receive port and the second input/output port I/O₂ can be an antenna port.

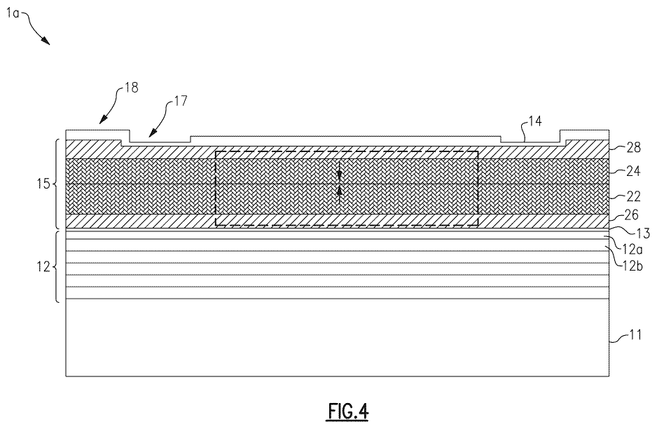

FIG. 6 is a schematic diagram of a ladder filter 120 that includes overtone mode BAW resonators and fundamental mode BAW resonators according to an embodiment. In the ladder filter 120, overtone mode resonators are implemented where they can have the largest impact on performance. Overtone mode BAW resonators can provide better power handling and linearity performance relative to fundamental mode BAW resonators. A first series resonator from an I/O port can have the largest impact on power handling. The first series resonator from the I/O port can have the largest impact on linearity. Accordingly, the first series resonator from the I/O port can be an overtone mode BAW resonator. Fundamental mode BAW resonators can be coupled to the I/O port by way of the first series overtone mode BAW resonator.

The ladder filter 120 can be implemented in higher power applications where the overtone mode BAW resonators provide desirable power handling characteristics. The ladder filter 120 can be a transmit filter. The ladder filter 120 can be implemented in higher frequency filtering applications (e.g., filtering RF signal with a frequency of over 5 GHz). The ladder filter 120 can have a passband in a frequency range from 5 GHz to 12 GHz, or in a frequency range from 5 GHz to 20 GHz. The ladder filter 120 can be used in 5G NR applications. For example, the ladder filter 120 can be a band pass filter with a passband corresponding to a 5G NR operating band.

The ladder filter 120 is like the ladder filter 100 of FIG. 5, except that the overtone mode BAW resonators R2, R3, R4, R5, R6, and R7 of the ladder filter 100 are replaced with fundamental mode BAW resonators R2', R3', R4', R5', R6', and R7′ in the ladder filter 120. The overtone mode BAW resonators R1, R8, and R9 of the ladder filter 120 can have the largest impact on power handling and/or linearity in certain applications. In various applications, the overtone mode BAW resonator R1 can be the first series resonator from an antenna port, the overtone mode BAW resonator R9 can be the first series resonator from a transmit port, and the overtone mode BAW resonator R8 can be the first shunt resonator from the transmit port. In some applications, the overtone mode BAW resonator R1 can be the first series resonator from a transmit port, the overtone mode BAW resonator R9 can be the first series resonator from an antenna port, and the overtone mode BAW resonator R8 can be the first shunt resonator from the antenna port.

The ladder filter 120 can achieve sufficient power handling and linearity for certain applications with overtone mode BAW resonators R1, R8, and R9 and fundamental mode BAW resonators R2′, R3′, R4′, R5′, R6′, and R7′. In the ladder filter 120, most of the acoustic resonators are fundamental mode BAW resonators. The ladder filter 120 includes fewer overtone mode BAW resonators than fundamental mode BAW resonators. Having some BAW resonators be fundamental mode resonators and other BAW resonators be overtone mode resonators can reduce a physical area of a filter relative to using all overtone mode BAW resonators because the fundamental mode BAW resonators can be smaller in physical size.

A first series fundamental mode BAW resonator from an I/O port (e.g., an antenna port) can be split into cascading BAW resonators to increase linearity in certain applications. With the first series resonator from the I/O port being an overtone mode BAW resonator, the reduced harmonic distortion and/or increased linearity of the overtone mode BAW resonator can provide sufficient performance such the BAW resonator can be implemented by a single series resonator without splitting. Accordingly, in embodiments disclosed herein, the first filter stage from an I/O port can include a single series overtone mode BAW resonator. In some instances, the first filter stage from the I/O port can also include at least one shunt acoustic resonator.

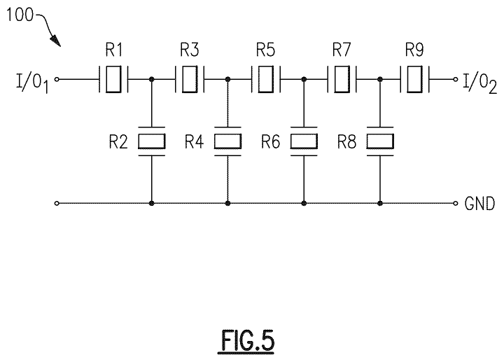

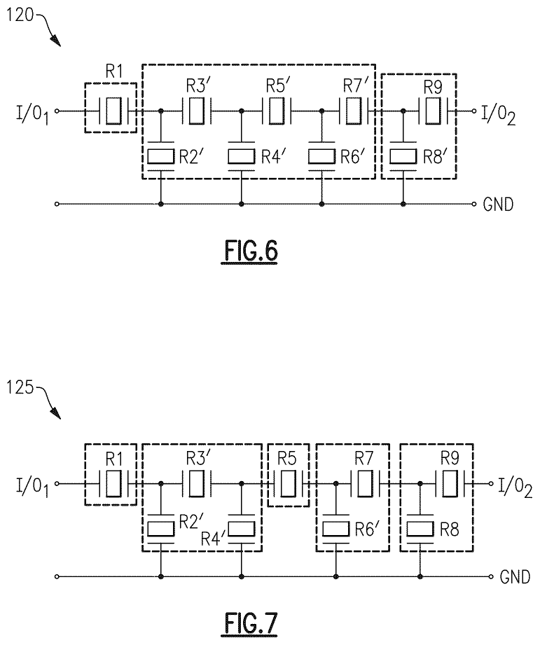

FIG. 7 is a schematic diagram of a ladder filter 125 that includes overtone mode BAW resonators and fundamental mode BAW resonators according to an embodiment. Any suitable resonator of a ladder filter can be an overtone mode BAW resonator for a particular application. Power dissipation analysis can be used to determine which resonators of a ladder filter to implement as an overtone mode BAW resonator. Overtone mode BAW resonators can be implemented for the resonators in which a dissipated power level is higher (e.g., where dissipated power is above a certain threshold). For example, power dissipation analysis can determine to replace fundamental mode BAW resonator R5′ from the ladder filter 120 of FIG. 6 with overtone mode BAW resonator R5 in the ladder filter 125. Any other fundamental mode BAW resonator of the ladder filter 120 can be alternatively or additionally be replaced with an overtone mode BAW resonator.

While some other embodiments related to filters that include an overtone mode BAW resonator and a fundamental mode BAW resonator, any suitable principles and advantages discussed herein can be implemented with two different suitable types of BAW resonators with one or more different characteristics. For instance, a filter can include a BAW resonators of a first type and a BAW resonators of a second type, where the BAW resonator of the first type has better power handling than the BAW resonator of the second type. The BAW resonator of the first type can also have better linearity than the BAW resonator of the second type. The BAW resonator of the first type can be implemented in an acoustic wave filter where more power handling is desired. The BAW resonator of the second type can be implemented in the filter topology in a location such that the acoustic wave filter still meets power handling specifications. An overtone mode BAW resonator is one example of the BAW resonator of the first type, and a fundamental mode BAW resonator is one example of the BAW resonator of the second type.

While some other embodiments related to filters that include an overtone mode BAW resonator and a fundamental mode BAW resonator, any suitable principles and advantages discussed herein can be implemented with other types of overtone mode resonators and fundamental mode resonators. For instance, a filter can include one or more surface acoustic wave overtone mode resonators and one or more surface acoustic wave fundamental mode resonators.

A bulk acoustic wave resonator disclosed herein can be arranged as a series resonator in a ladder filter to contribute to a lower frequency edge of a pass band of a band pass filter. A bulk acoustic wave resonator disclosed herein can be arranged as a series resonator in a ladder filter to contribute to an upper frequency edge of a pass band of a band pass filter. In an embodiment, a ladder filter can include a shunt resonator in accordance with any suitable principles and advantages disclosed herein and a series resonator in accordance with any suitable principles and advantages disclosed herein.

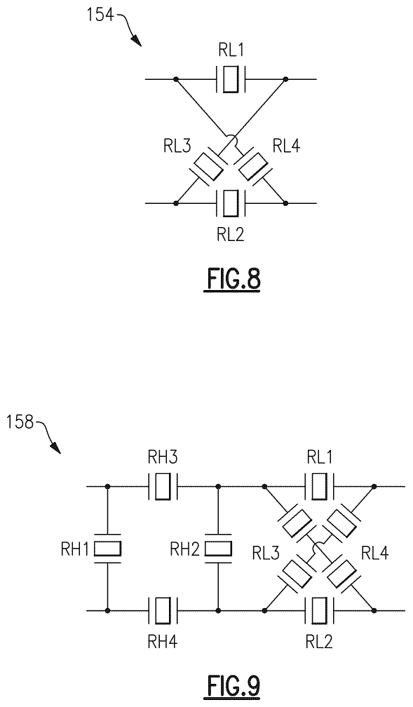

Bulk acoustic wave devices disclosed herein can be implemented as bulk acoustic wave resonators in a variety of filters. Such filters can be arranged to filter a radio frequency signal. While some example ladder filter topologies are discussed above, bulk acoustic wave devices disclosed herein can be implemented in a variety of different filter topologies. Examples of other filter topologies include without limitation, lattice filters, hybrid ladder lattice filters, notch filters where a notch is created by a BAW resonator, hybrid acoustic and non-acoustic inductor-capacitor filters, and the like. The example filter topologies can implement band pass filters. The example filter topologies can implement band stop filters. In some instances, bulk acoustic wave devices disclosed herein can be implemented in filters with one or more other types of resonators and/or with passive impedance elements, such as one or more inductors and/or one or more capacitors. Some example filter topologies will now be discussed with reference to FIGS. 8 and 9. Any suitable combination of features of the filter topologies of FIGS. 8 to 9 can be implemented together with each other and/or with other filter topologies.

FIG. 8 is a schematic diagram of a lattice filter 154 that includes a bulk acoustic wave resonator according to an embodiment. The lattice filter 154 is an example topology that can form a band pass filter from acoustic wave resonators. The lattice filter 154 can be arranged to filter an RF signal. As illustrated, the lattice filter 154 includes acoustic wave resonators RL1, RL2, RL3, and RL4. The acoustic wave resonators RL1 and RL2 are series resonators. The acoustic wave resonators RL3 and RL4 are shunt resonators. The illustrated lattice filter 154 has a balanced input and a balanced output. One or more of the illustrated acoustic wave resonators RL1 to RL4 can be a bulk acoustic wave resonator in accordance with any suitable principles and advantages disclosed herein.

FIG. 9 is a schematic diagram of a hybrid ladder and lattice filter 158 that includes a bulk acoustic wave resonator according to an embodiment. The illustrated hybrid ladder and lattice filter 158 includes series acoustic resonators RL1, RL2, RH3, and RH4 and shunt acoustic resonators RL3, RL4, RH1, and RH2. The hybrid ladder and lattice filter 158 includes one or more bulk acoustic wave resonators in accordance with any suitable principles and advantages disclosed herein.

One or more bulk acoustic wave resonators including any suitable combination of features disclosed herein be included in a filter arranged to filter a radio frequency signal in a fifth generation (5G) New Radio (NR) operating band within Frequency Range 1(FR1 ). A filter arranged to filter a radio frequency signal in a 5G NR operating band can include one or more BAW resonators disclosed herein. FR1 can be from 410 megahertz (MHz) to 7.125 gigahertz (GHz), for example, as specified in a current 5G NR specification. A filter with BAW devices disclosed herein can provide desirable power handling and/or linearity for 5G NR applications. A filter with BAW devices disclosed herein can provide filtering of relatively high frequency signals for 5G NR applications. One or more bulk acoustic wave resonators in accordance with any suitable principles and advantages disclosed herein can be included in a filter arranged to filter a radio frequency signal in a fourth generation (4G) Long Term Evolution (LTE) operating band. One or more acoustic wave resonators in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio - Dual Connectivity (ENDC) application. One or more bulk acoustic wave resonators in accordance with any suitable principles and advantages disclosed herein can be included in an acoustic wave filter for high frequency bands, such as frequency bands above 5 GHz and/or frequency bands above 5 GHz within FR1. BAW devices disclosed herein can be implemented in transmit filters, which typically have higher power handling specifications than receive filters.

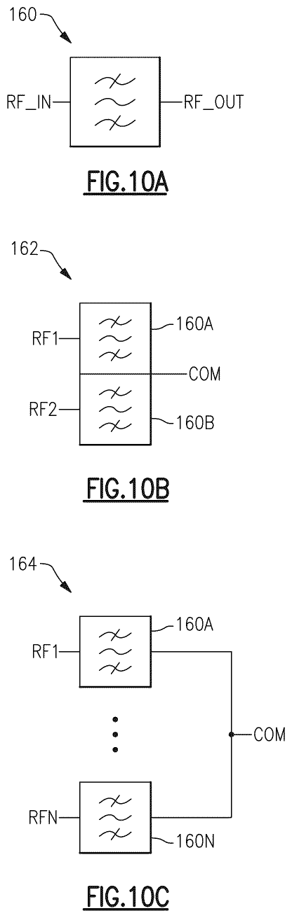

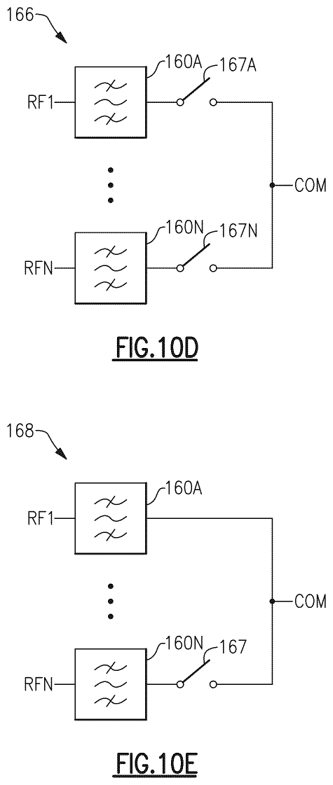

The bulk acoustic wave resonators disclosed herein can be implemented in a standalone filter and/or in a filter in any suitable multiplexer. The filter can be a band pass filter arranged to filter a 4G LTE band and/or 5G NR band. Examples of a standalone filter and multiplexers will be discussed with reference to FIGS. 10A to 10E. Any suitable principles and advantages of these filters and/or multiplexers can be implemented together with each other.

FIG. 10A is schematic diagram of an acoustic wave filter 160. The acoustic wave filter 160 is a band pass filter. The acoustic wave filter 160 is arranged to filter a radio frequency signal. The acoustic wave filter 160 includes one or more acoustic wave devices coupled between a first input/output port RF_IN and a second input/output port RF_OUT. The acoustic wave filter 160 includes a bulk acoustic wave resonator according to an embodiment.

FIG. 10B is a schematic diagram of a duplexer 162 that includes an acoustic wave filter according to an embodiment. The duplexer 162 includes a first filter 160A and a second filter 160B coupled to together at a common node COM. One of the filters of the duplexer 162 can be a transmit filter and the other of the filters of the duplexer 162 can be a receive filter. In some other instances, such as in a diversity receive application, the duplexer 162 can include two receive filters. Alternatively, the duplexer 162 can include two transmit filters. The common node COM can be an antenna node.

The first filter 160A is an acoustic wave filter arranged to filter a radio frequency signal. The first filter 160A includes one or more acoustic wave resonators coupled between a first radio frequency node RF1 and the common node COM. The first radio frequency node RF1 can be a transmit node or a receive node. The first filter 160A includes a bulk acoustic wave resonator in accordance with any suitable principles and advantages disclosed herein.

The second filter 160B can be any suitable filter arranged to filter a second radio frequency signal. The second filter 160B can be, for example, an acoustic wave filter, an acoustic wave filter that includes a bulk acoustic wave resonator in accordance with any suitable principles and advantages disclosed herein, an LC filter, a hybrid acoustic wave LC filter, or the like. The second filter 160B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of bulk acoustic wave devices in accordance with any suitable principles and advantages disclosed herein.

FIG. 10C is a schematic diagram of a multiplexer 164 that includes an acoustic wave filter according to an embodiment. The multiplexer 164 includes a plurality of filters 160A to 160N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 160A to 160N each have a fixed electrical connection to the common node COM. This can be referred to as hard multiplexing or fixed multiplexing. Filters have fixed electrical connections to the common node in hard multiplexing applications.

The first filter 160A is an acoustic wave filter arranged to filter a radio frequency signal. The first filter 160A can include one or more acoustic wave devices coupled between a first radio frequency node RF1 and the common node COM. The first radio frequency node RF1 can be a transmit node or a receive node. The first filter 160A includes a bulk acoustic wave resonator in accordance with any suitable principles and advantages disclosed herein. The other filter(s) of the multiplexer 164 can include one or more acoustic wave filters, one or more acoustic wave filters that include a bulk acoustic wave resonator in accordance with any suitable principles and advantages disclosed herein, one or more LC filters, one or more hybrid acoustic wave LC filters, the like, or any suitable combination thereof.

FIG. 10D is a schematic diagram of a multiplexer 166 that includes an acoustic wave filter according to an embodiment. The multiplexer 166 is like the multiplexer 164 of FIG. 10C, except that the multiplexer 166 implements switched multiplexing. In switched multiplexing, a filter is coupled to a common node via a switch. In the multiplexer 166, the switches 167A to 167N can selectively electrically connect respective filters 160A to 160N to the common node COM. For example, the switch 167A can selectively electrically connect the first filter 160A the common node COM via the switch 167A. Any suitable number of the switches 167A to 167N can electrically connect a respective filter 160A to 160N to the common node COM in a given state. Similarly, any suitable number of the switches 167A to 167N can electrically isolate a respective filter 160A to 160N to the common node COM in a given state. The functionality of the switches 167A to 167N can support various carrier aggregations.

FIG. 10E is a schematic diagram of a multiplexer 168 that includes an acoustic wave filter according to an embodiment. The multiplexer 168 illustrates that a multiplexer can include any suitable combination of hard multiplexed and switched multiplexed filters. One or more bulk acoustic wave devices in accordance with any suitable principles and advantages disclosed herein can be included in a filter (e.g., the filter 160A) that is hard multiplexed to the common node COM of the multiplexer 168. Alternatively or additionally, one or more bulk acoustic wave devices in accordance with any suitable principles and advantages disclosed herein can be included in a filter (e.g., the filter 160N) that is switch multiplexed to the common node COM of the multiplexer 168.

The acoustic wave devices disclosed herein can be implemented in a variety of packaged modules. Some example packaged modules will now be disclosed in which any suitable principles and advantages of the acoustic wave devices, acoustic wave filters, or multiplexers disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example.

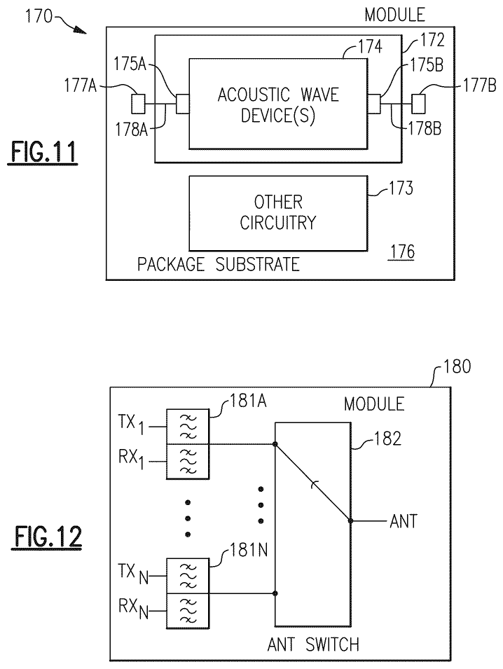

FIG. 11 is a schematic diagram of a radio frequency module 170 that includes an acoustic wave component 172 according to an embodiment. The illustrated radio frequency module 170 includes the acoustic wave component 172 and other circuitry 173. The acoustic wave component 172 can include an acoustic wave filter that includes a plurality of bulk acoustic wave resonators, for example.

The acoustic wave component 172 shown in FIG. 11 includes one or more acoustic wave devices 174 and terminals 175A and 175B. The one or more acoustic wave devices 174 include at least one bulk acoustic wave device implemented in accordance with any suitable principles and advantages disclosed herein. The terminals 175A and 175B can serve, for example, as an input contact and an output contact. Although two terminals are illustrated, any suitable number of terminals can be implemented for a particular application. The acoustic wave component 172 and the other circuitry 173 are on a common packaging substrate 176 in FIG. 11. The packaging substrate 176 can be a laminate substrate. The terminals 175A and 175B can be electrically connected to contacts 177A and 177B, respectively, on the packaging substrate 176 by way of electrical connectors 178A and 178B, respectively. The electrical connectors 178A and 178B can be bumps or wire bonds, for example.

The other circuitry 173 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 173 can include one or more radio frequency circuit elements. The other circuitry 173 can be electrically connected to the one or more acoustic wave devices 174. The radio frequency module 170 can include one or more packaging structures to, for example, provide protection and/or facilitate easier handling of the radio frequency module 170. Such a packaging structure can include an overmold structure formed over the packaging substrate 176. The overmold structure can encapsulate some or all of the components of the radio frequency module 170.

FIG. 12 is a schematic block diagram of a module 180 that includes duplexers 181A to 181N and an antenna switch 182. One or more filters of the duplexers 181A to 181N can include a bulk acoustic wave device in accordance with any suitable principles and advantages disclosed herein. Any suitable number of duplexers 181A to 181N can be implemented. The antenna switch 182 can have a number of throws corresponding to the number of duplexers 181A to 181N. The antenna switch 182 can include one or more additional throws coupled to one or more filters external to the module 180 and/or coupled to other circuitry. The antenna switch 182 can electrically couple a selected duplexer to an antenna port of the module 180.

FIG. 13 is a schematic block diagram of a module 190 that includes a power amplifier 192, a radio frequency switch 194, and duplexers 181A to 181N according to an embodiment. The power amplifier 192 can amplify a radio frequency signal. The radio frequency switch 194 can be a multi-throw radio frequency switch. The radio frequency switch 194 can electrically couple an output of the power amplifier 192 to a selected transmit filter of the duplexers 181A to 181N. One or more filters of the duplexers 181A to 181N can include a bulk acoustic wave device in accordance with any suitable principles and advantages disclosed herein. Any suitable number of duplexers 181A to 181N can be implemented.

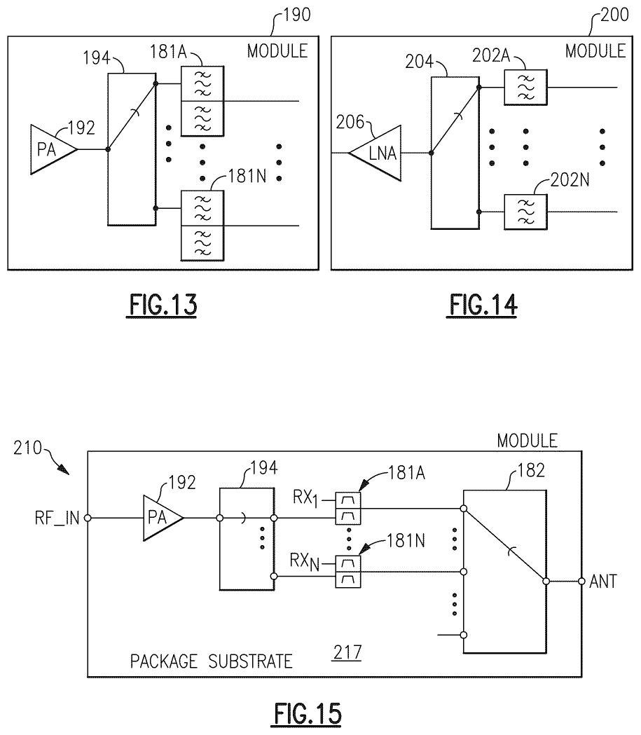

FIG. 14 is a schematic block diagram of a module 200 that includes filters 202A to 202N, a radio frequency switch 204, and a low noise amplifier 206 according to an embodiment. One or more filters of the filters 202A to 202N can include any suitable number of bulk acoustic wave devices in accordance with any suitable principles and advantages disclosed herein. Any suitable number of filters 202A to 202N can be implemented. The illustrated filters 202A to 202N are receive filters. One or more of the filters 202A to 202N can be included in a multiplexer that also includes a transmit filter and/or another receive filter. The radio frequency switch 204 can be a multi-throw radio frequency switch. The radio frequency switch 204 can electrically couple an output of a selected filter of filters 202A to 202N to the low noise amplifier 206. In some embodiments, a plurality of low noise amplifiers can be implemented. The module 200 can include diversity receive features in certain applications.

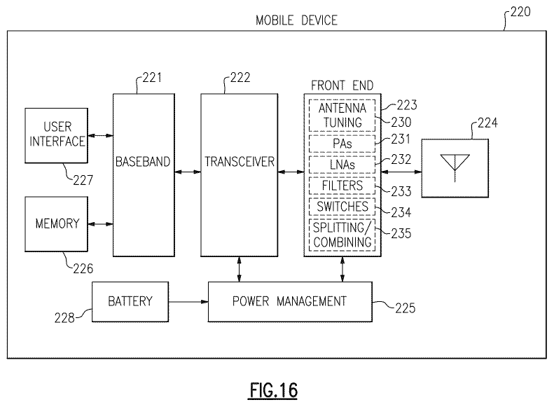

FIG. 15 is a schematic diagram of a radio frequency module 210 that includes an acoustic wave filter according to an embodiment. As illustrated, the radio frequency module 210 includes duplexers 181A to 181N, a power amplifier 192, a radio frequency switch 194 configured as a select switch, and an antenna switch 182. The radio frequency module 210 can include a package that encloses the illustrated elements. The illustrated elements can be disposed on a common packaging substrate 217. The packaging substrate 217 can be a laminate substrate, for example. A radio frequency module that includes a power amplifier can be referred to as a power amplifier module. A radio frequency module can include a subset of the elements illustrated in FIG. 15 and/or additional elements. The radio frequency module 210 may include any one of the acoustic wave filters that include at least one bulk acoustic wave resonator in accordance with any suitable principles and advantages disclosed herein.

The duplexers 181A to 181N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a bulk acoustic wave device in accordance with any suitable principles and advantages disclosed herein. Similarly, one or more of the receive filters can include a bulk acoustic wave device in accordance with any suitable principles and advantages disclosed herein. Although FIG. 15 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 192 can amplify a radio frequency signal. The illustrated radio frequency switch 194 is a multi-throw radio frequency switch. The radio frequency switch 194 can electrically couple an output of the power amplifier 192 to a selected transmit filter of the transmit filters of the duplexers 181A to 181N. In some instances, the radio frequency switch 194 can electrically connect the output of the power amplifier 192 to more than one of the transmit filters. The antenna switch 182 can selectively couple a signal from one or more of the duplexers 181A to 181N to an antenna port ANT. The duplexers 181A to 181N can be associated with different frequency bands and/or different modes of operation (e.g., different power modes, different signaling modes, etc.).

The bulk acoustic wave devices disclosed herein can be implemented in wireless communication devices. FIG. 16 is a schematic block diagram of a wireless communication device 220 that includes a filter according to an embodiment. The wireless communication device 220 can be a mobile device. The wireless communication device 220 can be any suitable wireless communication device. For instance, a wireless communication device 220 can be a mobile phone, such as a smart phone. As illustrated, the wireless communication device 220 includes a baseband system 221, a transceiver 222, a front end system 223, one or more antennas 224, a power management system 225, a memory 226, a user interface 227, and a battery 228.

The wireless communication device 220 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 222 generates RF signals for transmission and processes incoming RF signals received from the antennas 224. Various functionalities associated with the transmission and receiving of RF signals can be achieved by one or more components that are collectively represented in FIG. 16 as the transceiver 222. In one example, separate components (for instance, separate circuits or dies) can be provided for handling certain types of RF signals.

The front end system 223 aids in conditioning signals provided to and/or received from the antennas 224. In the illustrated embodiment, the front end system 223 includes antenna tuning circuitry 230, power amplifiers (PAs) 231, low noise amplifiers (LNAs) 232, filters 233, switches 234, and signal splitting/combining circuitry 235. However, other implementations are possible. The filters 233 can include one or more acoustic wave filters that include any suitable number of bulk acoustic wave devices in accordance with any suitable principles and advantages disclosed herein.

For example, the front end system 223 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 220 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 224 can include antennas used for a wide variety of types of communications. For example, the antennas 224 can include antennas for transmitting and/or receiving signals associated with a wide variety of frequencies and communications standards.

In certain implementations, the antennas 224 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 220 can operate with beamforming in certain implementations. For example, the front end system 223 can include amplifiers having controllable gain and phase shifters having controllable phase to provide beam formation and directivity for transmission and/or reception of signals using the antennas 224. For example, in the context of signal transmission, the amplitude and phases of the transmit signals provided to the antennas 224 are controlled such that radiated signals from the antennas 224 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 224 from a particular direction. In certain implementations, the antennas 224 include one or more arrays of antenna elements to enhance beamforming.

The baseband system 221 is coupled to the user interface 227 to facilitate processing of various user input and output (I/O), such as voice and data. The baseband system 221 provides the transceiver 222 with digital representations of transmit signals, which the transceiver 222 processes to generate RF signals for transmission. The baseband system 221 also processes digital representations of received signals provided by the transceiver 222. As shown in FIG. 16, the baseband system 221 is coupled to the memory 226 to facilitate operation of the wireless communication device 220.

The memory 226 can be used for a wide variety of purposes, such as storing data and/or instructions to facilitate the operation of the wireless communication device 220 and/or to provide storage of user information.

The power management system 225 provides a number of power management functions of the wireless communication device 220. In certain implementations, the power management system 225 includes a PA supply control circuit that controls the supply voltages of the power amplifiers 231. For example, the power management system 225 can be configured to change the supply voltage(s) provided to one or more of the power amplifiers 231 to improve efficiency, such as power added efficiency (PAE).

As shown in FIG. 16, the power management system 225 receives a battery voltage from the battery 228. The battery 228 can be any suitable battery for use in the wireless communication device 220, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz or in a frequency range from 5GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device comprising:
a solid acoustic mirror including alternating low acoustic impedance metal layers and high acoustic impedance metal layers; and
a piezoelectric stack including a first electrode, a second electrode, and a piezoelectric structure between the first electrode and the second electrode, the piezoelectric structure having a first piezoelectric layer with a first polarity orientation and a second piezoelectric layer with a second polarity orientation, the first polarity orientation and the second polarity orientation are substantially opposite so as to excite an overtone mode as a main mode of the bulk acoustic wave device.

2. The bulk acoustic wave device of claim 1 wherein the low acoustic impedance metal layers include titanium layers.

3. The bulk acoustic wave device of claim 2 wherein the high acoustic impedance metal layers include tungsten layers.

4. The bulk acoustic wave device of claim 2 wherein a thickness of a layer of the low acoustic impedance metal layers is in a range between 95 nm and 105 nm.

5. The bulk acoustic wave device of claim 1 wherein the low acoustic impedance metal layers include aluminum, magnesium, beryllium, or a metal that has an acoustic impedance of 30 MRayl or less.

6. The bulk acoustic wave device of claim 1 wherein the high acoustic impedance metal layers include tungsten (W), Osmium (Os), Iridium (Ir), or a metal that has an acoustic impedance of 90 MRayl or greater.

7. The bulk acoustic wave device of claim 1 wherein the first piezoelectric layer is an aluminum nitride layer with crystal orientation of (0±5, 0±5, 0±5) Euler angle.

8. The bulk acoustic wave device of claim 7 wherein the second piezoelectric layer is an aluminum nitride layer with crystal orientation of (0±5, 180±5, 0±5) Euler angle.

9. The bulk acoustic wave device of claim 8 wherein:
the low acoustic impedance metal layers include a titanium layer having a thickness in a range between 95 nm and 105 nm;
the high acoustic impedance metal layers include a tungsten layers having a thickness in a range between 85 nm and 95 nm; and
a thickness of the piezoelectric structure is 400 nm or more.

10. The bulk acoustic wave device of claim 1 wherein the piezoelectric structure has a thickness in a range between 400 nm and 500 nm.

11. The bulk acoustic wave device of claim 1 wherein the piezoelectric structure has a thickness that enables the bulk acoustic wave device to operate at a frequency of 10 GHz or higher.

12. The bulk acoustic wave device of claim 1 wherein the piezoelectric structure further includes a third piezoelectric layer with a third polarity orientation positioned between the second piezoelectric layer and the second electrode.

13. The bulk acoustic wave device of claim 12 wherein the second polarity orientation and the third polarity orientation are substantially opposite.

14. The bulk acoustic wave device of claim 12 wherein the piezoelectric structure has a thickness in a range between 740 nm and 820 nm.

15. The bulk acoustic wave device of claim 1 further comprising a frame structure in a frame region.

16. The bulk acoustic wave device of claim 15 wherein the frame structure includes a recessed frame structure and a raised frame structure.

17. The bulk acoustic wave device of claim 15 wherein the piezoelectric layer is less piezoelectric in the frame region than in a main active region.

18. The bulk acoustic wave device of claim 1 wherein the first piezoelectric layer is in contact with the second piezoelectric layer.

19. A radio frequency module comprising:
an acoustic wave filter including a bulk acoustic wave device including a solid acoustic mirror and a piezoelectric stack, the solid acoustic mirror including alternating low acoustic impedance metal layers and high acoustic impedance metal layers, the piezoelectric stack including a first electrode, a second electrode, and a piezoelectric structure between the first electrode and the second electrode, the piezoelectric structure having a first piezoelectric layer with a first polarity orientation and a second piezoelectric layer with a second polarity orientation, the first polarity orientation and the second polarity orientation are substantially opposite; and
a radio frequency circuit element coupled to the acoustic wave filter, the acoustic wave filter and the radio frequency circuit element being enclosed within a common package.

20. A wireless communication device comprising:
an acoustic wave filter including a bulk acoustic wave device including a solid acoustic mirror and a piezoelectric stack, the solid acoustic mirror including alternating low acoustic impedance metal layers and high acoustic impedance metal layers, the piezoelectric stack including a first electrode, a second electrode, and a piezoelectric structure between the first electrode and the second electrode, the piezoelectric structure having a first piezoelectric layer with a first polarity orientation and a second piezoelectric layer with a second polarity orientation, the first polarity orientation and the second polarity orientation are substantially opposite;
an antenna operatively coupled to the acoustic wave filter;
a radio frequency amplifier operatively coupled to the acoustic wave filter and configured to amplify a radio frequency signal; and
a transceiver in communication with the radio frequency amplifier.
